(19) United States
(12) Patent Application Publication
(10) Pub. No.: US 2022/0107139 A1
(43) Pub. Date: Apr. 7, 2022

(54) COOLING DEVICE AND COOLING SYSTEM

(71) Applicant: Nidec Chaun-Choung Technology Corporation, New Taipei City (TW)

(72) Inventors: Masashi TAKAO, New Taipei City (TW); Po-Chou SHIH, New Taipei City (TW)

(21) Appl. No.: 17/491,612

(22) Filed: Oct. 1, 2021

(30) Foreign Application Priority Data
Oct. 2, 2020 (JP) 2020-168096

(51) Int. Cl. F28D 15/04; F28D 9/00

(52) U.S. Cl. CPC F28D 15/04; F28D 9/0062

(57) ABSTRACT

A cooling device includes at least one fin laminated body which extends in a first direction and includes fins laminated in a second direction perpendicular to the first direction, and a heat conductor which extends in the second direction and is inside the fin laminated body. A second-direction interval between adjacent ones of the fins on one side of the fin laminated body in the first direction is greater than another second-direction interval between adjacent ones of the fins on another side of the fin laminated body in the first direction.

### CROSS-REFERENCE TO RELATED APPLICATIONS

The present application claims priority under 35 U.S.C. § 119 to Japanese Patent Application No. 2020-168096, filed on Oct. 2, 2020, the entire contents of which are hereby incorporated herein by reference.

### FIELD OF THE INVENTION

The present disclosure relates to a cooling device.

### BACKGROUND

Conventionally, a cooling device is used for cooling a heating element. The cooling device often has a plurality of fins. When a cooling medium such as air flows between the fins adjacent to each other in the plurality of fins, heat from the heating element often moves to the cooling medium.

In recent years, for example, cooling of a CPU, a GPU, or the like provided in a server device has become important, and it is desired to improve cooling performance when a cooling device is used for such cooling.

### SUMMARY

An example embodiment of a cooling device of the present disclosure includes at least one fin laminated body which extends in a first direction and includes fins laminated in a second direction perpendicular to the first direction, and a heat conductor which extends in the second direction and is inside the fin laminated body. A second-direction interval between adjacent ones of the fins on one side of the fin laminated body in the first direction is greater than another second-direction interval between adjacent ones of the fins on another side of the fin laminated body in the first direction.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view of a cooling system according to an example embodiment of the present disclosure.

FIG. 2 is a schematic side sectional view of a cooling device according to an example embodiment of the present disclosure.

FIG. 3 is a schematic view illustrating a flow between fins of a cooling medium according to an example embodiment of the present disclosure.

FIG. 4 is a schematic sectional view illustrating a section of a heat conductor according to an example embodiment of the present disclosure.

FIG. 5 is a view illustrating a fin of a first example embodiment of the present disclosure as viewed in a third direction.

FIG. 6 is an enlarged perspective view of a portion of the fin according to the first example embodiment of the present disclosure.

FIG. 7 is a view illustrating a fin of a second example embodiment of the present disclosure as viewed in the third direction.

FIG. 8 is a perspective view illustrating a partial configuration of a fin according to a third example embodiment of the present disclosure.

### DETAILED DESCRIPTION

Example embodiments of the present disclosure will be described below with reference to the drawings.

In the drawings, a first direction is defined as an X direction, one side in the first direction is defined as X1, and the other side in the first direction is defined as X2. As will be described later, the first direction is a direction in which a cooling medium A flows, one side in the first direction corresponds to an upstream side, and the other side in the first direction corresponds to a downstream side.

A direction perpendicular to the first direction is defined as a second direction (Y direction), one side in the second direction is defined as Y1, and the other side in the second direction is defined as Y2. Further, a direction perpendicular to the first direction and the second direction is defined as a third direction (Z direction), one side in the third direction is defined as Z1, and the other side in the third direction is defined as Z2.

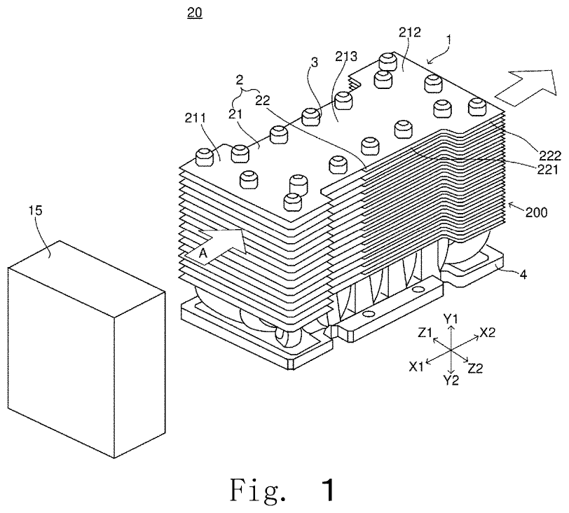

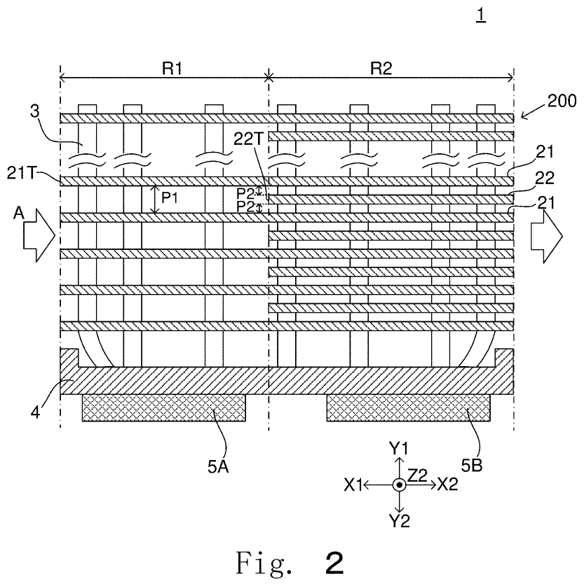

FIG. 1 is a perspective view illustrating a configuration of a cooling system 20 according to an example embodiment of the present disclosure. The cooling system 20 includes a cooling device 1 and a fan device 15. The cooling device 1 and the fan device 15 may be integrated. Further, FIG. 2 is a schematic sectional view of the cooling device 1 as viewed from one side in the third direction.

The cooling device 1 is a device which cools a plurality of heating elements 5A and 5B (FIG. 2) disposed in the first direction by using the cooling medium A. The cooling medium A is air. That is, the cooling device 1 is an air-cooling type device.

The heating elements 5A and 5B are preferably, for example, a CPU or a GPU provided in the server device. In this case, the cooling device 1 is mounted on the server device. The heating elements 5A and 5B may be, for example, power transistors of an inverter included in a traction motor for driving wheels of a vehicle. The power transistor is, for example, an insulated gate bipolar transistor (IGBT). In this case, the cooling device 1 is mounted on the traction motor. The number of heating elements may be a plurality other than two, or may be one.

The cooling device 1 includes a fin laminated body 200, a plurality of heat conductors 3, and a base member 4.

The fin laminated body 200 includes a plurality of fins 2. The plurality of fins 2 include a plurality of first fins 21 and a plurality of second fins 22. The first fin 21 and the second fin 22 have different shapes, and are plate-like members extending in the first direction and having the second direction as a thickness direction. The first fin 21 and the second fin 22 are formed of, for example, an aluminum alloy.

The first fins 21 and the second fins 22 are alternately disposed in the second direction. The fin laminated body 200 is configured by laminating the first fin 21 and the second fin 22 in the second direction. That is, the fin laminated body 200 includes the plurality of fins 2 extending in the first direction and disposed to be laminated in the second direction.

The first fin 21 includes wide portions 211 and 212 and a narrow portion 213 (FIG. 1). The wide portions 211 and 212 are wider in the third direction than the narrow portion 213. The narrow portion 213 is sandwiched in the first direction by the wide portions 211 and 212. The wide portion 211 is disposed on one side in the first direction with respect to the wide portion 212. Accordingly, the first fin 21 has an H shape as viewed in the second direction.

The second fin 22 includes a narrow portion 221 and a wide portion 222. The wide portion 222 is wider in the third direction than the narrow portion 221. The wide portion 222 is disposed on the other side of the narrow portion 221 in the first direction. Accordingly, the second fin 22 has a T shape as viewed in the second direction.

The wide portion 222 of the second fin 22 overlaps the wide portion 212 of the first fin 21 as viewed in the second direction. The narrow portion 221 of the second fin 22 overlaps a part of the narrow portion 213 of the first fin 21 on the other side in the first direction as viewed in the second direction.

As illustrated in FIG. 2, a region where the first fin 21 and the second fin 22 do not overlap each other on the upstream side as viewed in the second direction is a first region R1. That is, in the first region R1, the first fins 21 are adjacent to each other in the second direction.

As illustrated in FIG. 2, a region where the first fin 21 and the second fin 22 overlap each other on the downstream side as viewed in the second direction is a second region R2.

As illustrated in FIG. 2, the plurality of fins 2 include the first fin 21 extending from the first region R1 on one side in the first direction to the second region R2 on the other side in the first direction, and the second fin 22 extending from one end of the second region R2 in the first direction to the other end in the first direction. The second fin 22 is disposed to be sandwiched by the first fins 21 from both sides of the second direction.

Here, the first fin 21 may be configured to be divided in the first direction by the first region R1 and the second region R2. In this case, each of the divided portions has a T shape. However, it is necessary to position the divided fins in the second direction at the time of assembling the fins. On the other hand, in the case of the first fin 21 as illustrated in FIG. 2, such positioning is unnecessary. Therefore, the cooling device 1 can be easily manufactured.

In a case where the divided fins are used as described above, the fin laminated body is formed on each of one side in the first direction and the other side in the first direction. That is, it is sufficient if the cooling device 1 has at least one fin laminated body.

The shapes of the first fin 21 and the second fin 22 are not limited to the above, and may be, for example, rectangular when viewed in the second direction.

Each of the plurality of heat conductors 3 is configured as a heat pipe extending in the second direction. Each of the plurality of heat conductors 3 penetrates the fin laminated body 200 from the other side in the second direction to the one side in the second direction. That is, the heat conductor 3 extends in the second direction and is disposed inside the fin laminated body 200. For example, the end portion of the heat conductor 3 on one side in the second direction may not protrude from the fin 2 disposed closest to one side in the second direction.

The plurality of fins 2 are connected to the heat conductor 3 by, for example, caulking, heat welding, bonding, or the like. The detailed configuration of the heat conductor 3 will be described later.

In the arrangement example of the heat conductor 3 illustrated in FIG. 1, in the wide portion 211 of the first fin 21, three heat conductors 3 are disposed in the third direction on one side in the first direction, and two heat conductors 3 are disposed in the third direction on the other side in the first direction. Further, in the narrow portion 213 of the first fin 21, a set of two heat conductors 3 are arranged in the third direction, and three sets are arranged in the first direction. In the wide portion 212 of the first fin 21, three heat conductors 3 are disposed in the third direction on the other side in the first direction, and two heat conductors 3 are disposed in the third direction on one side in the first direction.

As illustrated in FIG. 2, among the sets of the heat conductors 3 disposed in the narrow portion 213, the set closest to on the one side in the first direction is disposed in the first region R1, and the remaining two sets are disposed in the second region R2.

The base member 4 is a metal member formed of, for example, an aluminum alloy, and has a plate shape with the second direction as a thickness direction. The base member 4 is disposed on the other side of the plurality of heat conductors 3 in the second direction. The end portion of each of the plurality of heat conductors 3 on the other side in the second direction is connected to the base member 4. In the example of FIG. 1, the end portion of the heat conductor 3 on the other side in the second direction has a bent shape, but may have a shape extending in the second direction, for example.

As illustrated in FIG. 2, the heating elements 5A and 5B are disposed on the other side of the base member 4 in the second direction. The heating elements 5A and 5B are directly or indirectly connected to the bottom surface (the outer surface on the other side in the second direction) of the base member 4. The heating element 5A is disposed in the first region R1, and the heating element 5B is disposed in the second region R2.

In a case where three heating elements are cooled, for example, one heating element may be disposed in the first region R1, another heating element may be disposed from the first region R1 to the second region R2, and the remaining heating element may be disposed in the second region R2. Alternatively, a single heating element disposed from the first region R1 to the second region R2 may be cooled.

As illustrated in FIG. 1, the fan device 15 is disposed on one side in the first direction with respect to the cooling device 1. The flow (air flow) of the cooling medium A generated by the fan device 15 flows into between the fins 2 from one side of the fin laminated body 200 in the first direction. The cooling medium A flowing between the fins 2 is discharged to the other side of the fin laminated body 200 in the first direction. Accordingly, the flow direction of the cooling medium A becomes the first direction (X direction), the upstream side corresponds to one side in the first direction, and the downstream side corresponds to the other side in the first direction.

The heat generated by the heating elements 5A and 5B is transferred to the fins 2 via the base member 4 and the heat conductor 3, and is dissipated to the cooling medium A flowing between the fins 2. Accordingly, the heating elements 5A and 5B can be cooled.

Here, as illustrated in FIG. 2, in the first region R1, the second-direction interval P1 between the fins 2 adjacent to each other in the second direction is an interval between the adjacent first fins 21. Further, in the second region R2, the second-direction interval P2 between the fins 2 adjacent to each other in the second direction is an interval between the first fin 21 and the second fin 22 adjacent to each other. In the example of FIG. 2, in the fin laminated body 200, all the second-direction intervals P1 are the same. Further, in the fin laminated body 200, all the second-direction intervals P2 are the same. Further, the second-direction interval P1 is wider than the second-direction interval P2.

In a case where the cooling medium A flows in between the fins 2 from one side of the fin laminated body 200 in the first direction, the cooling medium A flowing between the fins 2 (first fins 21) on the upstream side has a relatively low temperature and is sufficiently cooled on the upstream side. Thus, even when the second-direction interval P1 of the fins 2 on the upstream side is widened to reduce the heat-dissipation area of the fins 2, there is no influence on cooling of the heating element. Even when the cooling performance is improved by increasing the flow rate of the cooling medium A flowing into the cooling device 1, the pressure loss can be suppressed and the decrease in the flow rate of the cooling medium A flowing between the fins 2 on the upstream side can be suppressed by widening the second-direction interval P1 between the fins 2 on the upstream side. Accordingly, the cooling performance on the upstream side can be improved. Further, noise can be reduced by suppressing the pressure loss.

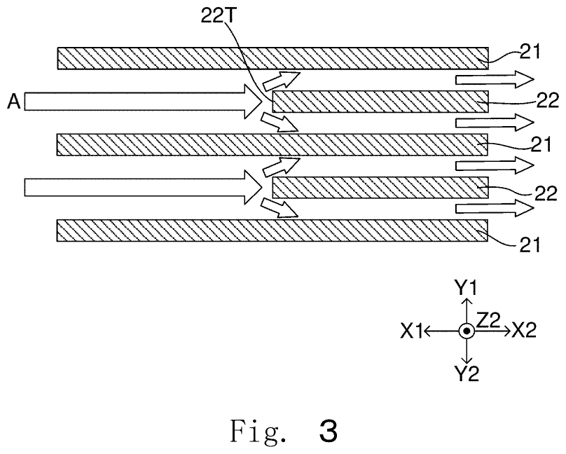

The inflow cooling medium A collides with an upstream end portion 21T (FIG. 2) of the fin 2 (first fin 21) having the upstream portion to generate a turbulent flow, but the flow approaches a laminar flow by flowing between the fins 2 on the upstream side. However, the number of fins 2 on the downstream side is larger than that on the upstream side, and the cooling medium A collides with an upstream end portion 22T of the fin 2 (second fin 22) on the downstream side disposed at the second direction position between the fins 2 on the upstream side, so that a turbulent flow can be generated again. Accordingly, the cooling performance on the downstream side can be improved. Here, FIG. 3 illustrates that when the cooling medium A flowing from the upstream side is branched by the second fin 22 and flows to the downstream side, a turbulent flow is generated on the downstream side due to the collision at the upstream end portion 22T.

In a case where the flow of the cooling medium A is a laminar flow, heat exchange is actively performed in a boundary layer between the fin 2 and the cooling medium A, but the heat exchange is less likely to be performed when the cooling medium A moves away from the boundary layer. On the other hand, when the flow of the cooling medium A is a turbulent flow, the pressure and the flow rate change irregularly, so that the boundary layer between the fin 2 and the cooling medium A is actively exchanged, and the heat exchange is more actively performed. Since the heat exchange in the fluid is performed in a wider range than the laminar flow due to the turbulence of the flow, the substantial heat transfer coefficient is increased. Therefore, the cooling capacity is improved at the place where the turbulent flow is generated.

Therefore, in a case where the fan device 15 having a large air volume is used, the cooling performance of the cooling device 1 can be improved.

For example, in the fin laminated body 200, the first fins 21 may be laminated in the second direction at the second-direction interval P2 in a partial region in the second direction. In this case, in the partial region, the interval between the fins 2 is the same on the upstream side and the downstream side. That is, it is sufficient if the second-direction interval P1 between adjacent fins 2 on one side in the first direction in at least one of the plurality of fins 2 is wider than the second-direction interval P2 between adjacent fins 2 on the other side in the first direction in at least one of the plurality of fins 2.

In the example of FIG. 2, the position of the second fin 22 is set as the second-direction center position between the first fins 21 positioned on both sides in the second direction of the second fin 22, and thus the second-direction interval P2 is the same on one side of the second fin 22 in the second direction and the other side in the second direction. However, the second-direction interval P2 may be made different between one side in the second direction and the other side in the second direction of the second fin 22 by shifting the position of the second fin 22 from the center position in the second direction. Further, the number of the second fins 22 positioned between the first fins 21 may be plural.

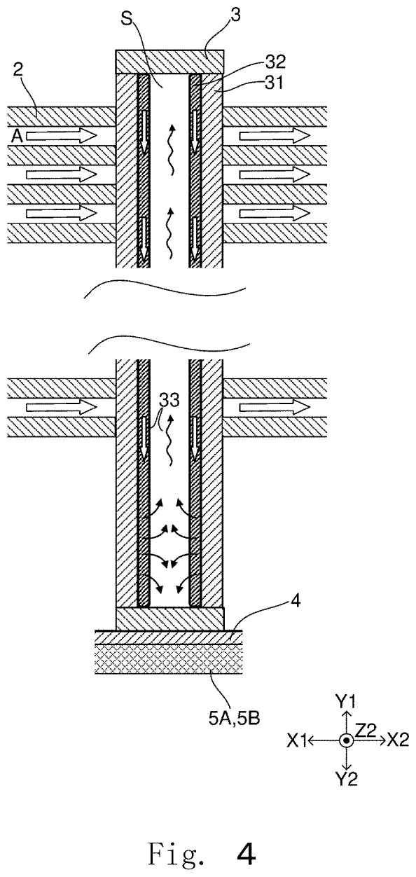

FIG. 4 is a schematic partial sectional view of the cooling device 1 as viewed in the third direction. FIG. 4 is a view of the state of being cut at a place of the heat conductor 3. In FIG. 4, the configuration of the other end portion of the heat conductor 3 in the second direction is simplified for convenience.

As illustrated in FIG. 4, the heat conductor 3 includes a housing 31 and a wick structure 32. The housing 31 is configured by sealing both end portions of a pipe extending in a longitudinal direction, and has a space S therein. The wick structure 32 has a pipe shape extending in the longitudinal direction and is disposed along the entire circumference of the inner surface of the housing 31. Further, a working medium 33 is accommodated in the space S. That is, the heat conductor 3 also includes the working medium 33. The working medium 33 is water, for example, but may be another liquid such as alcohol. The wick structure 32 includes, for example, a porous copper sintered body which transports the working medium 33.

As illustrated in FIG. 4, the vapor generated by vaporizing the working medium 33 by the heat of the heating elements 5A and 5B moves to one side in the second direction in the space S. The moved vapor is liquefied by cooling by the fins 2 and is refluxed to the other side in the second direction by the wick structure 32. In FIG. 4, the flow of the vaporized working medium 33 is indicated by a solid arrow, and the reflux of the liquefied working medium 33 is indicated by a white arrow.

At this time, when the cooling device 1 is installed such that the second direction is a vertical direction (gravity direction), and the other side in the second direction is the ground side, the working medium easily returns to the heating elements 5A and 5B side by gravity, and the cooling performance of the heating elements 5A and 5B can be improved.

The installation direction of the cooling device 1 is not limited to the above, and for example, the other side in the second direction may be set as the wall surface side of the installation target equipment.

Various example embodiments described below can be applied to the configuration of the fin 2 described above.

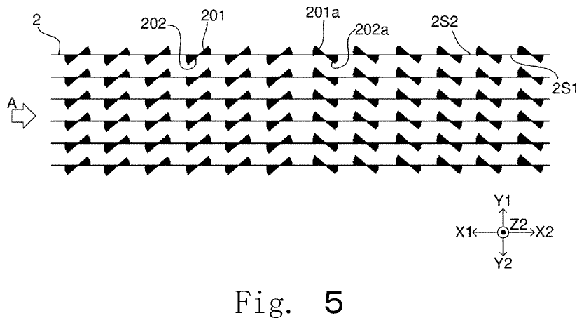

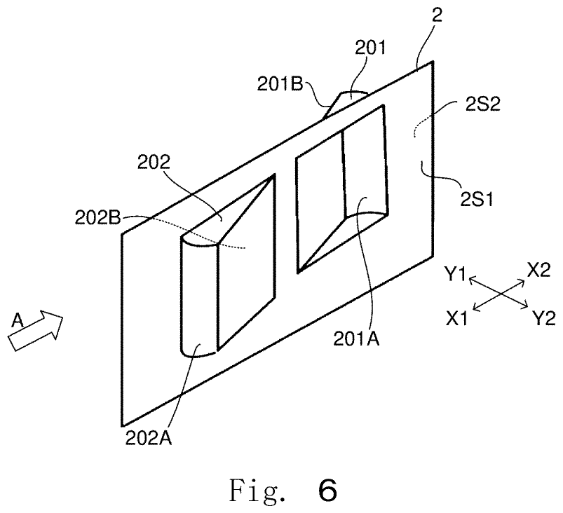

FIG. 5 is a view illustrating the first example embodiment of the fin 2 as viewed in the third direction. FIG. 5 illustrates the fins 2 arranged in the second direction. Further, FIG. 6 is an enlarged perspective view of a part of the fin 2 according to the first example embodiment.

As illustrated in FIG. 5, in the fin 2, a set including the first recess 201 and the second recess 202 is arranged in the first direction. That is, the fin 2 has the first recess 201 and the second recess 202.

As illustrated in FIG. 6, the fin 2 has a first guide surface 2S1 and a second guide surface 2S2 facing each other in the second direction. That is, the fin 2 has two guide surfaces 2S1 and 2S2. The first guide surface 2S1 and the second guide surface 2S2 extend along the first direction to guide the cooling medium A.

As illustrated in FIG. 6, the first recess 201 is recessed from the first guide surface 2S1 toward the second guide surface 2S2. That is, the first recess 201 is recessed from the one guide surface 2S1 toward the other guide surface 2S2. The first recess 201 has a fan shape as viewed in the third direction (FIG. 5). Accordingly, the first recess 201 has the first opposing surface 201A including the fan-shaped arc portion as an edge on the first guide surface 2S1 side, and has the second opposing surface 201B including the fan-shaped diameter portion as an edge on the second guide surface 2S2 side. That is, the opposing surfaces 201A and 201B are provided in the first recess 201.

The opposing surfaces 201A and 201B face a direction in which the cooling medium A flows. That is, at least one of the plurality of fins 2 has the opposing surfaces 201A and 201B facing the first direction. Further, the opposing surfaces 201A and 201B are disposed between both end portions of the fin 2 in the first direction. Accordingly, the turbulent flow of the cooling medium A is easily generated in the vicinity of the opposing surfaces 201A and 201B.

When the first recess 201 is provided, opposing surfaces such as the opposing surfaces 201A and 201B can be provided on both guide surface sides.

As illustrated in FIG. 6, the fin 2 has the second recess 202. The second recess 202 is disposed on one side of the first recess 201 in the first direction. The second recess 202 is recessed from the second guide surface 2S2 toward the first guide surface 2S1. That is, the second recess 202 is recessed from the other guide surface 2S2 toward the one guide surface 2S1. The second recess 202 has a fan shape as viewed from above (FIG. 5). Accordingly, the second recess 202 has a third opposing surface 202A including the fan-shaped arc portion as an edge on the first guide surface 2S1 side, and has the fourth opposing surface 202B including the fan-shaped diameter portion as an edge on the second guide surface 2S2 side. The opposing surfaces 202A and 202B are provided between both end portions of the fin 2 in the first direction.

Since the opposing surfaces 202A and 202B face the first direction, the turbulent flow of the cooling medium A is easily generated in the vicinity of the opposing surfaces 202A and 202B. Further, when the first recess 201 and the second recess 202 are provided, the cooling medium A smoothly flows along the outer surface of the second recess 202, which protrudes toward the first guide surface 2S1, on one side in the first direction and the inner surface of the first recess 201, which is recessed toward the second guide surface 2S2, on the other side in the first direction, and the cooling medium A smoothly flows along the inner surface of the second recess 202, which is recessed toward the first guide surface 2S1, on one side in the first direction and the outer surface of the first recess 201, which protrudes toward the second guide surface 2S2, on the other side in the first direction.

As illustrated in FIG. 5, the first recesses 201 included in the fins 2 disposed adjacent to each other in the second direction are recessed toward one side in the second direction in the same direction. Accordingly, the interval between the first recesses 201 adjacent to each other in the second direction becomes substantially constant along the first direction. Therefore, the cooling medium A smoothly flows between the adjacent first recesses 201.

As illustrated in FIG. 5, in the fin 2, the first recess 201a recessed toward the second guide surface 2S2 may be disposed on one side in the first direction, and the second recess 202a recessed toward the first guide surface 2S1 may be disposed on the other side in the first direction. Then, as illustrated in FIG. 5, in the middle of the fin 2 in the first direction, the arrangement of the set of the first recess 201 and the second recess 202 in the first direction may be switched to the arrangement of the set of the first recess 201a and the second recess 202a in the first direction.

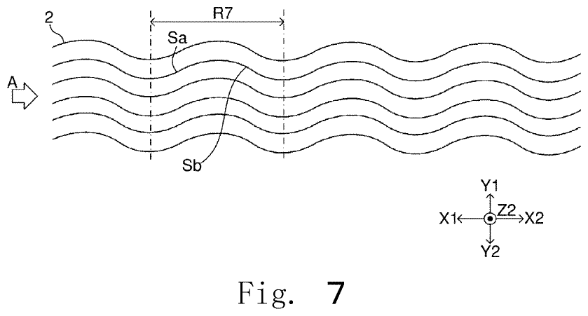

FIG. 7 is a view illustrating a second example embodiment of the fin 2 as viewed in the third direction. FIG. 7 illustrates the fins 2 arranged in the second direction.

As illustrated in FIG. 7, as viewed in the third direction, toward the other side in the first direction, at least one of the plurality of fins 2 repeatedly extends toward one side in the second direction and then extends toward the other side in the second direction as indicated by a range R7 as an example. In FIG. 7, the fin 2 has a curved wave shape (range R7) repeatedly extending in the first direction.

Accordingly, in the fin 2, a opposing surface Sa is formed on one side in the second direction, and a opposing surface Sb is formed on the other side in the second direction. Since the opposing surfaces Sa and Sb face the first direction, the turbulent flow of the cooling medium A is easily generated in the vicinity of the opposing surfaces Sa and Sb.

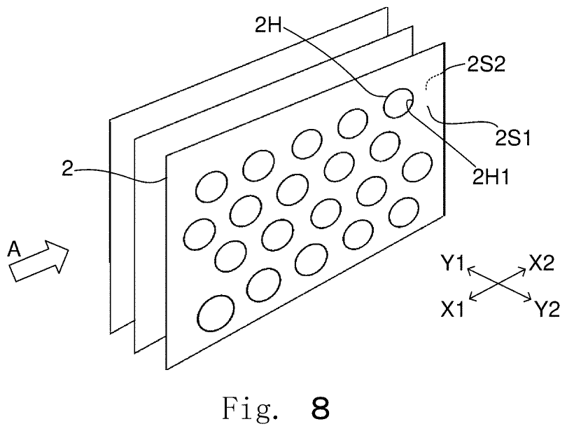

FIG. 8 is a schematic perspective view illustrating a partial configuration of the fin 2 according to a third example embodiment. As illustrated in FIG. 8, at least one of the plurality of fins 2 has two guide surfaces 2S1 and 2S2 which extend along the first direction, guide the cooling medium A, and face each other. Further, the fin 2 has a through-hole 2H penetrating from one guide surface 2S1 to the other guide surface 2S2.

Accordingly, a part of the through-hole 2H becomes a opposing surface 2H1 facing the first direction. That is, the opposing surface 2H1 is provided in the through-hole 2H.

Therefore, the turbulent flow of the cooling medium A is easily generated in the vicinity of the opposing surface 2H1. The opposing surface 2H1 can be formed by a simple method of forming the through-hole 2H in the fin 2. Further, it is also easy to form a large number of through-holes 2H in the fin 2.

The example embodiment of the present disclosure has been described above. The scope of the present disclosure is not limited to the above example embodiment. The present disclosure can be implemented by making various modifications to the abovementioned example embodiment without departing from the gist of the disclosure. In addition, the matters described in the above example embodiments can be arbitrarily combined together, as appropriate, as long as there is no inconsistency.

For example, the cooling medium A in which the turbulent flow is generated in the second region R2 (FIG. 2) approaches the laminar flow by flowing between the fins 2, and is discharged from the fin laminated body 200 to the other side in the first direction. Therefore, the cooling device 1 may be further disposed on the other side in the first direction of the cooling device 1, and the discharged cooling medium A may flow into the cooling device 1 at the subsequent stage.

The cooling medium A is not limited to air, and may be water, for example. In this case, the cooling device 1 is a water-cooled device.

The present disclosure can be used, for example, for cooling various heating elements.

Features of the above-described preferred example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
at least one fin laminated body which extends in a first direction and includes fins laminated in a second direction perpendicular to the first direction; and
a heat conductor which extends in the second direction and is inside the fin laminated body; wherein
a second-direction interval between adjacent ones of the fins on one side of the fin laminated body in the first direction is greater than another second-direction interval between adjacent ones of the fins on another side of the fin laminated body in the first direction.

2. The cooling device according to claim 1, wherein
the fins include:
first fins which extend from a first region on the one side in the first direction to a second region on the another side in the first direction; and
a second fin which extends from an end of the second region on the one side in the first direction to another end on the another side in the first direction; and
the second fin is sandwiched by the first fins from both sides of the second direction.

3. The cooling device according to claim 1, wherein
at least one of the fins includes an opposing surface opposing the first direction; and
the opposing surface is between two end portions of the fin in the first direction.

4. The cooling device according to claim 3, wherein
the at least one of the fins includes:
two guide surfaces which extend in the first direction, guide a cooling medium, and oppose each other; and
a first recess which is recessed from one of the guide surfaces toward another one of the guide surfaces; and
the opposing surface is provided in the first recess.

5. The cooling device according to claim 4, wherein
the at least one of the fins includes a second recess on one side of the first recess in the first direction; and
the second recess is recessed from the another one of the guide surfaces toward the one of the guide surfaces.

6. The cooling device according to claim 5, wherein the first recesses in adjacent pairs of the fins in the second direction are recessed in a same direction.

7. The cooling device according to claim 6, wherein as viewed in a third direction perpendicular to the first direction and the second direction, toward the other side in the first direction, at least one of the fins includes an edge which repeatedly extends toward one side in the second direction and then extends toward another side in the second direction.

8. The cooling device according to claim 7, wherein
at least one of the fins includes:
two guide surfaces which extend in the first direction, guide the cooling medium, and oppose each other; and
a through-hole which penetrates from one of the guide surfaces to another one of the guide surfaces; and
one of the two guides surfaces is provided in the through-hole.

9. The cooling device according to claim 1, wherein
the heat conductor includes:
a housing which includes a space therein;
a wick structure which is on an inner surface of the housing; and
a working medium which is accommodated in the space, and
the second direction is a vertical direction.

10. A cooling system comprising:
the cooling device according to claim 1; and
a fan on one side of the first direction with respect to the cooling device.
